(19) United States
(12) Patent Application Publication
(10) Pub. No.: US 2026/0018144 A1
(43) Pub. Date: Jan. 15, 2026

(54) DISPLAY DEVICE

(71) Applicant: PANASONIC AUTOMOTIVE SYSTEMS CO., LTD., Kanagawa (JP)

(72) Inventors: Kohsuke MASUDA, Kanagawa (JP); Yuichi WAKAYAMA, Aichi (JP)

(73) Assignee: PANASONIC AUTOMOTIVE SYSTEMS CO., LTD., Kanagawa (JP)

(21) Appl. No.: 19/335,841

(22) Filed: Sep. 22, 2025

Related U.S. Application Data
(63) Continuation of application No. PCT/JP2023/044580, filed on Dec. 13, 2023.

(30) Foreign Application Priority Data
Mar. 29, 2023 (JP) 2023-053888

(51) Int. Cl. G09G 3/36

(52) U.S. Cl. CPC G09G 3/3648; G09G 2300/0408; G09G 2330/06

(57) ABSTRACT

The present disclosure is to prevent leakage of electromagnetic noise in a display device. The display device includes: a conductive housing electrically connected to a ground; one or a plurality of optical members accommodated in the housing; a conductive frame sandwiching the optical member with the housing, a part of the frame being in direct or indirect contact with the housing; a liquid crystal portion disposed along a surface of the frame; and a control circuit connected to the liquid crystal portion and configured to control the liquid crystal portion. The frame and the control circuit are separated.

### TECHNICAL FIELD

The present disclosure relates to a display device.

### BACKGROUND ART

Patent Literature 1 discloses a liquid crystal device including a liquid crystal display panel, a first support member, and a shield member. The liquid crystal display panel has an installation area for installing a driver IC that is an example of an electronic component. The first support member is conductive, accommodates the liquid crystal display panel, and is electrically connected to a reference potential V_{GND} such as 0 V. The shield member includes an insulating layer and a conductive layer. The driver IC is fixed by the insulating layer of the shield member via a bonding agent or the like, and the conductive layer is electrically connected to the first support member. Accordingly, noise generated from the driver IC or the like or the outside is guided to the first support member via the shield member and finally dissipated to the reference potential V_{GND}.

### CITATION LIST

### Patent Literature

Patent Literature 1: JP2010-072272A

### SUMMARY OF INVENTION

It may be difficult to provide a shield member that shields electromagnetic noise due to structural restrictions, manufacturing process restrictions, and the like. In such a case, it is required to prevent leakage of the electromagnetic noise by a method different from a method of providing a shield member.

An object of the present disclosure is to prevent leakage of electromagnetic noise in a display device.

A display device according to an aspect of the present disclosure includes: a conductive housing electrically connected to a ground; one or a plurality of optical members accommodated in the housing; a conductive frame sandwiching the optical member with the housing, a part of the frame being in direct or indirect contact with the housing; a liquid crystal portion disposed along a surface of the frame; and a control circuit connected to the liquid crystal portion and configured to control the liquid crystal portion, in which the frame and the control circuit are separated.

According to the present disclosure, leakage of electromagnetic noise in a display device can be prevented.

### BRIEF DESCRIPTION OF DRAWINGS

FIG. 1 is a perspective view illustrating a configuration example of a display device according to an embodiment;

FIG. 2 is an exploded perspective view illustrating the configuration example of the display device according to the present embodiment;

FIG. 3 is a cross-sectional view of the display device in FIG. 1 taken along a line A-A′;

FIG. 4 is a cross-sectional view of the display device in FIG. 1 taken along a line B-B′; and

FIG. 5 shows EMI noise of the display device according to the present embodiment.

### DESCRIPTION OF EMBODIMENTS

Hereinafter, an embodiment of the present disclosure will be described in detail with reference to the drawings as appropriate. Overly detailed description may be omitted. For example, detailed description of already well-known matters and redundant description of substantially the same configuration may be omitted. This is to avoid redundancy of the following description and to facilitate understanding of those skilled in the art. The attached drawings and the following description are provided for those skilled in the art to sufficiently understand the present disclosure, and are not intended to limit the subject matter described in the claims.

### Present Embodiment

### <Configuration of Display Device>

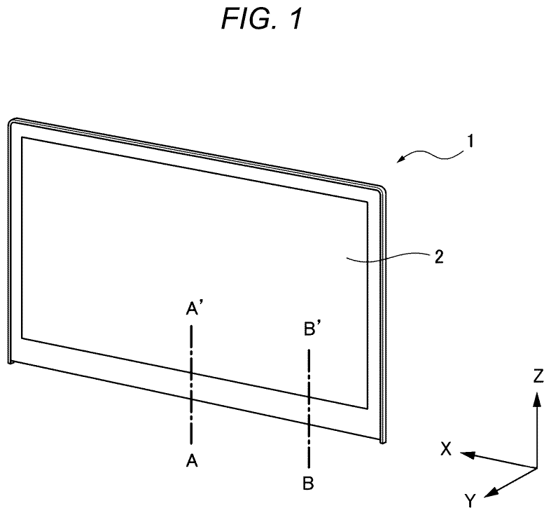

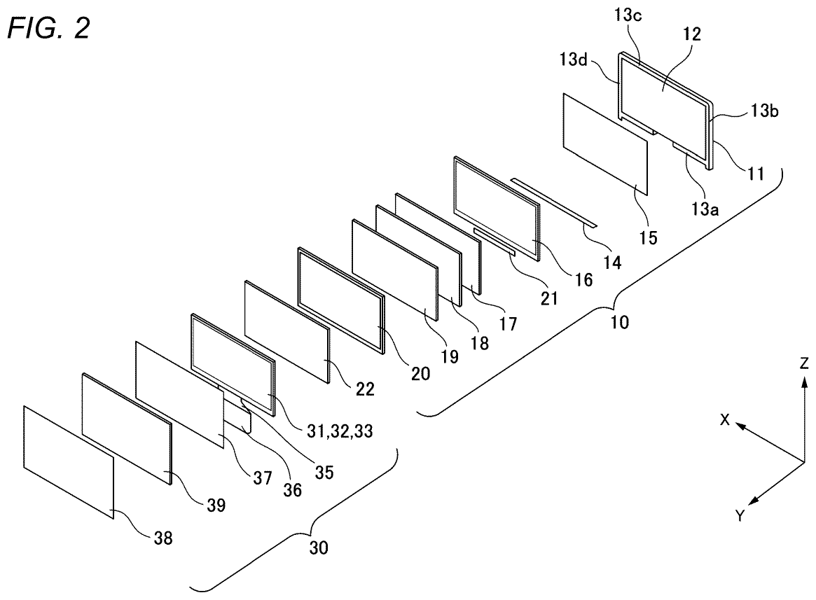

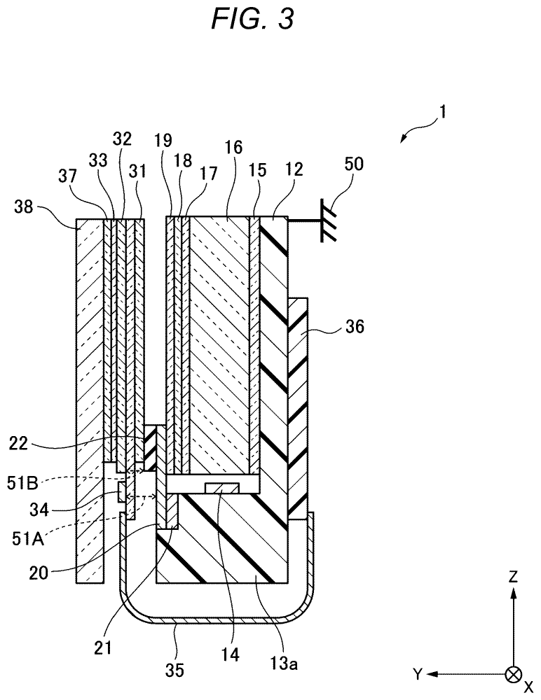

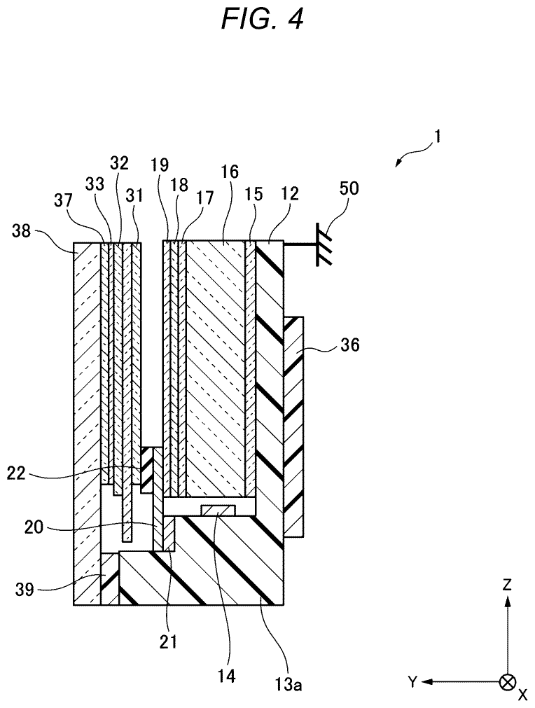

FIG. 1 is a perspective view illustrating a configuration example of a display device 1 according to an embodiment. FIG. 2 is an exploded perspective view illustrating the configuration example of the display device 1 according to the present embodiment. FIG. 3 is a cross-sectional view of the display device 1 in FIG. 1 taken along a line A-A′. FIG. 4 is a cross-sectional view of the display device 1 in FIG. 1 taken along a line B-B′. Sizes and positions of members constituting the display device 1 illustrated in the drawings are examples, and the sizes and the positions of the members constituting the display device 1 according to the present embodiment are not limited to those in the drawings.

The display device 1 according to the present embodiment is a device for displaying an image, and is mounted on a vehicle as, for example, one of devices constituting an in-vehicle infotainment (IVI) system. As illustrated in FIG. 1, the display device 1 has a flat rectangular parallelepiped shape and includes a screen 2 that can display an image on a main surface.

For convenience of description, in the present embodiment, as illustrated in FIG. 1, a longitudinal direction of the screen 2 of the display device 1 is defined as an X-axis, a lateral direction of the screen 2 is defined as a Z-axis, and a direction perpendicular to the screen 2 is defined as a Y-axis. For convenience of description, a positive direction of the Z-axis may be referred to as “upper”, a negative direction of the Z-axis may be referred to as “lower”, a positive direction of the X-axis may be referred to as “left”, and a negative direction of the X-axis may be referred to as “right”, a positive direction of the Y-axis may be referred to as “front”, a negative direction of the Y-axis may be referred to as “rear”. For convenience of description, a surface on a positive side of the Y-axis in a ZX plane may be referred to as a front surface, and a surface on a negative side of the Y-axis in the ZX plane may be referred to as a back surface. Expressions related to these directions are used for convenience of description, and are not intended to limit a posture of the structure in actual use. For example, the display device 1 may be used in a posture in which the longitudinal direction of the screen 2 is a vertical direction and the lateral direction of the screen 2 is a horizontal direction (that is, in a vertical orientation).

As illustrated in FIGS. 2, 3, and 4, the display device 1 includes a housing 11, a light emitting unit 14, a reflective sheet 15, a light guide plate 16, a diffusion sheet 17, a prism sheet 18, a brightness enhancement film 19, a front frame 20, a first double-sided tape 21, a cushion 22, a first polarizing plate 31, a liquid crystal portion 32, a second polarizing plate 33, a drive circuit 34, a flexible substrate 35, a print board 36, a bonding portion 37, a cover glass 38, and a second double-sided tape 39.

The housing 11 includes a rectangular main surface 12 and walls 13a, 13b, 13c, and 13d extending forward (in the positive direction of the Y-axis) from four sides of the main surface 12. The housing 11 includes a conductive member (for example, a metal member). An example of the metal member included in the housing 11 includes a magnesium alloy. The housing 11 is electrically connected to a ground 50 having a reference potential (0 V). The housing 11 may be substituted with a rear frame or a die-cast.

As illustrated in FIG. 2, the light emitting unit 14 has a narrow elongated shape extending in a left-right direction, and as illustrated in FIG. 3 or 4, is disposed on the lower wall 13a of the housing 11 and emits light upward. The light emitting unit 14 is implemented by, for example, a light emitting diode (LED).

The reflective sheet 15 is a thin rectangular sheet and is disposed along a front surface of the main surface 12 of the housing 11 (for example, in close contact with the front surface of the main surface 12 of the housing 11). The reflective sheet 15 reflects light emitted from the light emitting unit 14 and light leaking rearward from the light guide plate 16.

The light guide plate 16 is a thin rectangular plate and is disposed along a front surface of the reflective sheet 15 (for example, in close contact with the front surface of the reflective sheet 15). The light guide plate 16 diffuses light received from the light emitting unit 14 to an entire surface. Accordingly, the entire surface of the light guide plate 16 emits light.

The diffusion sheet 17 is a thin rectangular sheet and is disposed along a front surface of the light guide plate 16 (for example, in close contact with the front surface of the light guide plate 16). The diffusion sheet 17 diffuses light output from the light guide plate 16 and makes luminance uniform.

The prism sheet 18 is a thin rectangular sheet and is disposed along a front surface of the diffusion sheet 17 (for example, in close contact with the front surface of the diffusion sheet 17). The prism sheet 18 improves luminance of light output from the diffusion sheet 17.

The brightness enhancement film 19 is a thin rectangular film, and is disposed along a front surface of the prism sheet 18 (for example, in close contact with the front surface of the prism sheet 18). The brightness enhancement film 19 enhances brightness of light output from the prism sheet 18.

As illustrated in FIG. 2, the front frame 20 has a rectangular frame shape (that is, a shape with only a quadrangular frame and no central portion), and sandwiches the brightness enhancement film 19, the prism sheet 18, the diffusion sheet 17, the light guide plate 16, and the reflective sheet 15 with the main surface 12 of the housing 11. At least one of the brightness enhancement film 19, the prism sheet 18, the diffusion sheet 17, the light guide plate 16, and the reflective sheet 15 sandwiched between the front frame 20 and the main surface 12 of the housing 11 may be referred to as an optical member. The front frame 20 includes a conductive member (for example, a metal member). An example of the metal member included in the front frame 20 includes stainless steel (SUS).

As illustrated in FIG. 3 or FIG. 4, the front frame 20 has, near an outer periphery thereof, an end portion bonded to the walls 13a, 13b, 13c, and 13d of the housing 11 by the first double-sided tape 21 that is an example of a bonding member. The end portion of the front frame 20 near the outer periphery may be a part outward of the main surface 12 of the housing 11 (that is, a part facing the walls 13a, 13b, 13c, and 13d). The first double-sided tape 21 includes a conductive member.

A member in which the housing 11, the light emitting unit 14, the reflective sheet 15, the light guide plate 16, the diffusion sheet 17, the prism sheet 18, the brightness enhancement film 19, the front frame 20, and the first double-sided tape 21 are assembled may be referred to as a backlight module 10.

The cushion 22 is an example of an elastic body, has a rectangular frame shape (that is, a shape with only a quadrangular frame and no central portion), and is disposed on a front surface of the front frame 20. The cushion 22 may be disposed on the entire front surface of the front frame 20. The cushion 22 may include a conductive member. The cushion 22 may have a thickness of, for example, 0.5 mm to 1.0 mm.

The first polarizing plate 31 is a thin rectangular plate, and is disposed along a front surface of the brightness enhancement film 19 (for example, parallel to the front surface of the brightness enhancement film 19) and along a front surface of the cushion 22 (for example, in close contact with the front surface of the cushion 22). The first polarizing plate 31 transmits light polarized in a prescribed first direction among light output from the brightness enhancement film 19, and blocks light polarized in other directions.

The liquid crystal portion 32 is a thin rectangular device and is disposed along a front surface of the first polarizing plate 31 (for example, in close contact with the front surface of the first polarizing plate 31). The liquid crystal portion 32 includes a liquid crystal molecule for each sub-pixel, and controls polarization when light output from the first polarizing plate 31 passes through each sub-pixel based on voltage control.

The second polarizing plate 33 is a thin rectangular plate and is disposed along a front surface of the liquid crystal portion 32 (for example, in close contact with the front surface of the liquid crystal portion 32). The second polarizing plate 33 transmits light polarized in a second direction orthogonal to the first direction among light output from the liquid crystal portion 32, and blocks light polarized in other directions.

As illustrated in FIG. 3, the drive circuit 34 is disposed on a lower front surface of the liquid crystal portion 32. The drive circuit 34 controls pixels (or sub-pixels) of the liquid crystal portion 32. The drive circuit 34 may control a touch on the screen 2 of the liquid crystal portion 32. The drive circuit 34 may be disposed at a position overlapping the front frame 20 or the cushion 22 when viewed from a direction perpendicular to a surface of the liquid crystal portion 32 (that is, when viewed in the Y-axis direction). The drive circuit 34 may be a touch display driver integration (TDDI). Two or more drive circuits 34 may be provided.

The flexible substrate 35 has one end connected to the drive circuit 34, and extends downward. The flexible substrate 35 may be substituted with a flexible printed circuit (FPC). Two or more flexible substrates 35 may be provided.

The flexible substrate 35 has the other end connected to the print board 36. The print board 36 is disposed on a back surface of the housing 11. The print board 36 may be substituted with a printed circuit board (PCB). Two or more print boards 36 may be provided.

As illustrated in FIG. 3, the flexible substrate 35 is bent in a U shape, passes a lower side of the housing 11, and connects the drive circuit 34 and the print board 36.

A member in which the first polarizing plate 31, the liquid crystal portion 32, the second polarizing plate 33, the drive circuit 34, the flexible substrate 35, and the print board 36 are assembled may be provided as a so-called open cell.

The bonding portion 37 is provided along a front surface of the second polarizing plate 33 (for example, in close contact with the front surface of the second polarizing plate 33). The bonding portion 37 may be an optical clear resin (OCR) or an optical clear adhesive (OCA).

The cover glass 38 is disposed along a front surface of the bonding portion 37 (for example, in close contact with the front surface of the bonding portion 37). As illustrated in FIGS. 2 and 4, the cover glass 38 has, near sides thereof, end portions bonded to the walls 13a, 13b, 13c, and 13d of the housing 11 by the second double-sided tape 39 that is an example of a bonding member.

A member in which the first polarizing plate 31, the liquid crystal portion 32, the second polarizing plate 33, the drive circuit 34, the flexible substrate 35, the print board 36, the bonding portion 37, the cover glass 38, and the second double-sided tape 39 are assembled may be referred to as a liquid crystal module 30.

That is, the display device 1 is formed by assembling the liquid crystal module 30 to the backlight module 10 with the cushion 22 sandwiched in between. With the cushion 22 sandwiched in between, it is possible to absorb an impact on the liquid crystal module 30 and prevent foreign matters from entering between the backlight module 10 and the liquid crystal module 30.

### <EMI Noise Countermeasure>

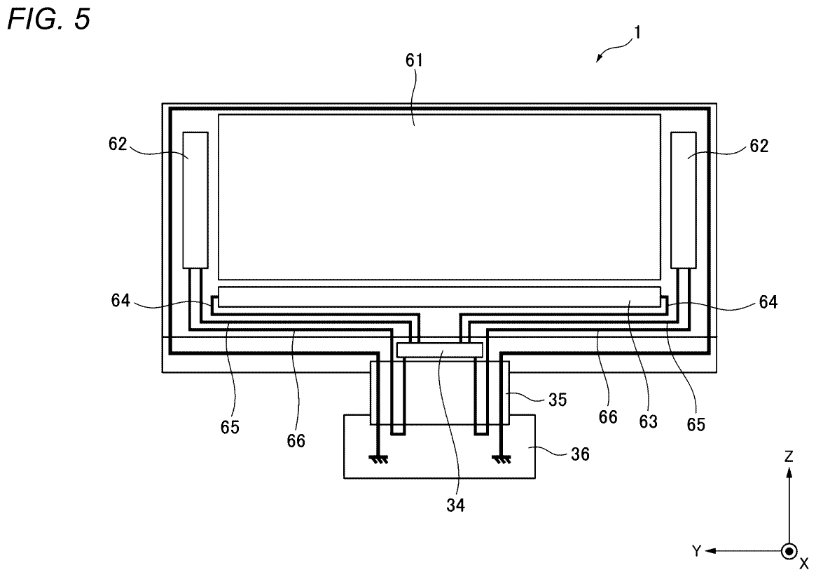

FIG. 5 shows EMI noise of the display device 1 according to the present embodiment.

As illustrated in FIG. 5, the liquid crystal portion 32 includes an active area 61 (that is, the screen 2) that is an area implemented by a plurality of pixels and can display an image, gate circuits 62 disposed on left and right sides of the active area 61, and a DEMUX circuit 63 disposed below the active area 61. The DEMUX circuit 63 may be disposed at a position overlapping the front frame 20 or the cushion 22 when viewed from a direction perpendicular to a surface of the liquid crystal portion 32 (that is, when viewed in the Y-axis direction). The gate circuits 62 control pixels of the active area 61 based on a gate control signal. The DEMUX circuit 63 controls DEMUX of an image displayed in the active area 61 based on a MUX signal.

The drive circuit 34 is connected to the DEMUX circuit 63 by a signal line 64, and transmits the MUX signal through the signal line 64. The drive circuit 34 is connected to the gate circuit 62 via a signal line 65, and transmits the gate control signal via the signal line 65. The drive circuit 34 is connected to the print board 36 through the flexible substrate 35 and the signal line 66, the print board 36 is connected to the gate circuit 62 through the flexible substrate 35 and the signal line 66, and the drive circuit 34 and/or the print board 36 transmit VGH and/or VGL through the flexible substrate 35 and the signal line 66.

Hereinafter, a circuit including at least one of the drive circuit 34 and the DEMUX circuit 63 is referred to as a control circuit. When executing driving, the control circuit generates electromagnetic noise (including conduction noise and radiation noise). Hereinafter, the electromagnetic noise generated by the control circuit is referred to as EMI noise. The EMI noise may cause electromagnetic interference with other electronic devices. For example, when leaking to the outside of the display device 1 mounted on a vehicle, the EMI noise may interfere with radio waves used in the vehicle or affect behaviors of other electronic devices mounted on the vehicle. Examples of devices that handle radio waves used in the vehicle include car radios that receive AM waves and FM waves, car televisions that receive broadcast waves, and wireless communication devices that perform wireless communication such as 4G, 5G, Wi-Fi, or Bluetooth.

The display device 1 according to the present embodiment prevents the leakage of the EMI noise. This will be described in detail below.

As described above, the front frame 20, the first double-sided tape 21, and the housing 11 include conductive members, and the housing 11 is connected to the ground 50. For this reason, the front frame 20 has a reference potential (0 V). The front frame 20 and the control circuit (the drive circuit 34 or the DEMUX circuit 63) are separated by a first distance 51A (see FIG. 3). Accordingly, a separation space between the front frame 20 and the control circuit serves as a virtual capacitor and generates capacitance. Therefore, the EMI noise is more strongly attracted to the front frame 20 in which capacitance is generated than to the cover glass 38. Therefore, the EMI noise can be prevented from leaking from the display device 1 to the outside.

Further, as described above, the cushion 22 in contact with the front frame 20 may include a conductive member. In this case, the cushion 22 has a reference potential (0 V). The cushion 22 and the control circuit (the drive circuit 34 or the DEMUX circuit 63) are separated by a second distance 51B (see FIG. 3). The cushion 22 is disposed closer to the control circuit than to the front frame 20, and thus the second distance 51B is shorter than the first distance 51A. Therefore, the separation space between the cushion 22 and the control circuit serves as a virtual capacitor and generates a larger capacitance than that in a case of the first distance 51A. Therefore, the EMI noise is more strongly attracted to the cushion 22, and can thus be more strongly prevented from leaking from the display device 1 to the outside.

The control circuit (the drive circuit 34 or the DEMUX circuit 63) may be disposed at a position overlapping the front frame 20 or the cushion 22 when viewed from the direction perpendicular to the surface of the liquid crystal portion 32 (that is, when viewed in the Y-axis direction). Accordingly, the control circuit and the front frame 20 or the cushion 22 are disposed at positions facing each other, and thus a larger capacitance can be generated.

As described above, according to the display device 1 in the present embodiment, the electromagnetic noise can be prevented from leaking from the display device 1 to the outside without providing an electromagnetic shield.

Although a case where the display device 1 is a liquid crystal display (LCD) has been described above, the display device 1 may be an organic electroluminescence diode (OLED) display. The above-described configuration for preventing leakage of the EMI noise to the outside is also applicable to the OLED display.

### Summary of Present Embodiment

Following techniques are disclosed based on the above-described description of the present embodiment.

### <Technique 1>

The display device 1 according to the present embodiment includes: the conductive housing 11 electrically connected to the ground 50; one or a plurality of optical members (for example, at least one of the reflective sheet 15, the light guide plate 16, the diffusion sheet 17, the prism sheet 18, and the brightness enhancement film 19) accommodated in the housing 11; a conductive frame (for example, the front frame 20) sandwiching the optical member with the housing 11, a part of the frame being in direct or indirect contact with the housing 11; the liquid crystal portion 32 disposed along a surface of the frame; and a control circuit (for example, the drive circuit 34 or the DEMUX circuit 63) connected to the liquid crystal portion 32 and configured to control the liquid crystal portion 32, in which the frame and the control circuit are separated from each other.

### <Technique 2>

In the display device 1 according to Technique 1, capacitance is generated between the control circuit and the frame.

According to Techniques 1 and 2, the conductive frame is electrically connected to the ground 50 through the housing 11 and the frame and the control circuit are separated. Accordingly, capacitance is generated between the frame and the control circuit. Accordingly, electromagnetic noise (EMI noise) generated from the control circuit is attracted to the frame, and thus can be prevented from leaking to the outside of the display device 1.

### <Technique 3>

The display device 1 according to Technique 1 or 2 further includes a conductive elastic body (for example, the cushion 22) disposed between the frame and the liquid crystal portion 32 and in contact with the frame, in which the elastic body and the control circuit are separated.

### <Technique 4>

In the display device 1 according to Technique 3, capacitance is generated between the control circuit and the elastic body.

According to Techniques 3 and 4, the conductive elastic body is electrically connected to the ground 50 through the frame and the housing 11 and the elastic body and the control circuit are separated. Accordingly, capacitance is generated between the elastic body and the control circuit. Accordingly, electromagnetic noise (EMI noise) generated from the control circuit is attracted to the elastic body, and thus can be prevented from leaking to the outside of the display device 1. A separation distance (second distance 51B) between the elastic body and the control circuit is shorter than a separation distance (first distance 51A) between the frame and the control circuit, and thus a larger capacitance is generated. Therefore, the electromagnetic noise generated from the control circuit is more strongly attracted to the elastic body, and thus the leakage of the electromagnetic noise to the outside of the display device 1 can be more strongly prevented.

### <Technique 5>

The display device 1 according to any one of Techniques 1 to 4 further includes a conductive bonding member (for example, the first double-sided tape 21) provided on the part of the frame in contact with the housing 11 and bonding the frame to the housing 11.

Accordingly, the frame is bonded to the housing 11 and is electrically connected to the ground 50 through the conductive bonding member and the housing 11.

### <Technique 6>

In the display device 1 according to any one of Techniques 1 to 5, the control circuit is disposed at a position overlapping the frame when viewed from a direction perpendicular to the surface of the liquid crystal portion 32.

Accordingly, the control circuit and the frame are disposed at positions facing each other, and thus a larger capacitance can be generated.

### <Technique 7>

In the display device 1 according to any one of Techniques 1 to 6, the control circuit is a touch display driver integration (TDDI) circuit related to the liquid crystal portion 32. Accordingly, it is possible to prevent electromagnetic noise generated from the TDDI from leaking to the outside of the display device 1.

### <Technique 8>

In the display device 1 according to any one of Techniques 1 to 7, the control circuit is the DEMUX circuit 63 related to the liquid crystal portion 32.

Accordingly, it is possible to prevent electromagnetic noise generated from the DEMUX circuit 63 from leaking to the outside of the display device 1.

### <Technique 9>

In the display device 1 according to any one of Techniques 1 to 8, the housing 11 and the frame include a metal member.

Accordingly, the housing 11 and the frame are conductive.

Although the embodiment has been described above with reference to the attached drawings, the present disclosure is not limited thereto. It is apparent to those skilled in the art that various modifications, corrections, substitutions, additions, deletions, and equivalents can be conceived within the scope described in the claims, and it is understood that such modifications, corrections, substitutions, additions, deletions, and equivalents also fall within the technical scope of the present disclosure. Components in the embodiment described above may be combined freely in a range without departing from the gist of the invention.

The present application is based on a Japanese patent application (JP2023-053888A) filed on Mar. 29, 2023, and contents thereof are incorporated herein by reference.

### INDUSTRIAL APPLICABILITY

The techniques of the present disclosure are useful for preventing leakage of electromagnetic noise.

### CROSS-REFERENCE TO RELATED APPLICATIONS

This is a continuation of International Application No. PCT/JP2023/044580 filed on Dec. 13, 2023, and claims priority from Japanese Patent Application No. 2023-053888 filed on Mar. 29, 2023, the entire content of which is incorporated herein by reference.

What is claimed is:

1. A display device comprising:
a conductive housing electrically connected to a ground;
one or a plurality of optical members accommodated in the housing;
a conductive frame sandwiching the optical member with the housing, a part of the frame being in direct or indirect contact with the housing;
a liquid crystal portion disposed along a surface of the frame; and
a control circuit connected to the liquid crystal portion and configured to control the liquid crystal portion, wherein
the frame and the control circuit are separated.

2. The display device according to claim 1, wherein
capacitance is generated between the control circuit and the frame.

3. The display device according to claim 1, further comprising:
a conductive elastic body disposed between the frame and the liquid crystal portion and in contact with the frame, wherein
the elastic body and the control circuit are separated.

4. The display device according to claim 3, wherein
capacitance is generated between the control circuit and the elastic body.

5. The display device according to claim 1, further comprising:
a conductive bonding member provided on the part of the frame in contact with the housing and bonding the frame to the housing.

6. The display device according to claim 1, wherein
the control circuit is disposed at a position overlapping the frame when viewed from a direction perpendicular to a surface of the liquid crystal portion.

7. The display device according to claim 1, wherein
the control circuit is a touch display driver integration (TDDI) circuit related to the liquid crystal portion.

8. The display device according to claim 1, wherein
the control circuit is a DEMUX circuit related to the liquid crystal portion.

9. The display device according to claim 1, wherein
the housing and the frame include a metal member.
